(19) United States
(12) Patent Application Publication
(10) Pub. No.: US 2024/0329537 A1
(43) Pub. Date: Oct. 3, 2024

(54) METAL CONTAINING PHOTORESIST DEVELOPER COMPOSITION, AND METHOD OF FORMING PATTERNS INCLUDING STEP OF DEVELOPING USING THE COMPOSITION

(71) Applicant: SAMSUNG SDI CO., LTD., Yongin-si (KR)

(72) Inventors: Taegeun SEONG, Suwon-si (KR); Hyungrang MOON, Suwon-si (KR); Yoojeong CHOI, Suwon-si (KR); Wanhee LIM, Suwon-si (KR); Chungheon LEE, Suwon-si (KR); Daeseok SONG, Suwon-si (KR); Jun SAKONG, Suwon-si (KR)

(21) Appl. No.: 18/509,184

(22) Filed: Nov. 14, 2023

(30) Foreign Application Priority Data
Mar. 29, 2023 (KR) 10-2023-0041362

(51) Int. Cl. G03F 7/32; G03F 7/004; G03F 7/16

(52) U.S. Cl. CPC G03F 7/32; G03F 7/0042; G03F 7/168

(57) ABSTRACT

A metal-containing photoresist developer composition, and a method of forming patterns including a step (e.g., an act or task) of developing using the same are provided. The metal-containing photoresist developer composition includes an organic solvent, an acid compound, and a conjugate base compound of the acid compound.

### CROSS-REFERENCE TO RELATED APPLICATION

The present application claims priority to and the benefit of Korean Patent Application No. 10-2023-0041362 filed in the Korean Intellectual Property Office on Mar. 29, 2023, the entire content of which is hereby incorporated by reference.

### BACKGROUND

### 1. Field

Embodiments of the present disclosure relate to a metal-containing photoresist developer composition and a method of forming patterns including a step (e.g., an act or task) of developing using the same.

### 2. Description of the Related Art

In recent years, a semiconductor industry has been accompanied by a continuous reduction of critical dimensions, and this dimensional reduction has led to new types of high-performance photoresist materials and a patterning method that provides for processing and patterning for increasingly smaller features.

Conventional chemically amplified (CA) photoresists are designed to secure high sensitivity, but because a typical elemental makeup thereof (for example, an elemental makeup including smaller quantities of O, F, and S, C) lowers absorbance at a wavelength of about 13.5 nm and as a result, reduces sensitivity, and the photoresists may suffer more difficulties, for example, under extreme ultraviolet (EUV) exposure. In addition, the CA photoresists may have difficulties due to roughness issues for small feature sizes, and due partially to the nature of acid catalyst processes, line edge roughness (LER) experimentally result in increases as a photospeed decreases. Due to these drawbacks and problems of the CA photoresist, a new type or kind of high-performance photoresist is desired and/or required in the semiconductor industry.

For example, it is desirable and/or necessary to develop a photoresist securing excellent or suitable etching resistance and resolution, and concurrently (e.g., simultaneously), improving sensitivity and enhancing critical dimension (CD) uniformity and line edge roughness (LER) characteristics in the photolithography process.

### SUMMARY

Aspects of one or more embodiments relate to a metal-containing photoresist developer composition.

Aspects of one or more embodiments relate to a method of forming patterns including a step (e.g., an act or task) of developing using the composition.

Additional aspects will be set forth in part in the description which follows and, in part, will be apparent from the description, or may be learned by practice of the presented embodiments of the disclosure.

A metal-containing photoresist developer composition according to one or more embodiments of the present disclosure includes an organic solvent, an acid compound, and a conjugate base compound of the acid compound.

In one or more embodiments, the acid compound may be (e.g., may be included in an amount of) about 0.01 to about 10 wt % based on a total wt % of the metal-containing photoresist developer composition.

In one or more embodiments, the conjugate base compound may be (e.g., may be included in an amount of) about 0.001 to about 1 wt % based on a total wt % of the metal-containing photoresist developer composition.

In one or more embodiments, the acid compound and the conjugate base compound may have a weight ratio of about 1:0.01 to about 1:1.

In one or more embodiments, the conjugate base compound may be derived from an ammonium salt, an alkali metal salt, an alkaline earth metal salt, or a combination thereof.

According to one or more embodiments of the present disclosure, a system for forming a photoresist pattern includes the metal-containing photoresist developer composition described above and a metal-containing photoresist including a metal compound including at least one of an organic tin oxo group or an organic tin carboxyl group.

In one or more embodiments, the metal-containing photoresist may include a metal compound represented by Chemical Formula 1.

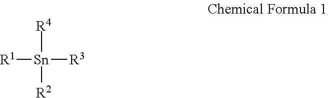

In Chemical Formula 1, R¹ may be (e.g., is selected from) a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, and/or —R^{a}—O—R^{b} (wherein R^{a} is a substituted or unsubstituted C1 to C20 alkylene group and R^{b} is a substituted or unsubstituted C1 to C20 alkyl group), R² to R⁴ are each independently selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, —OR^{c} or —OC(═O)R^{d}, at least one of R² to R⁴ are each independently (e.g., are each independently selected from) —OR^{c} or —OC(═O)R^{d}, R^{c} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and R^{d} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof. R^{c} and R^{d} may each independently be a substituted or unsubstituted C1 to C20 alkyl group.

A method of forming patterns according to one or more embodiments of the present disclosure includes coating a metal-containing photoresist composition on a substrate, drying and heating the metal-containing photoresist composition to form a metal-containing photoresist film on the substrate, exposing the metal-containing photoresist film to light, and developing the metal-containing photoresist film using the aforementioned metal-containing photoresist developer composition.

The metal-containing photoresist developer composition according to one or more embodiments may improve CD (critical dimension) uniformity by reducing or preventing and stabilizing an instantaneous pH imbalance caused by acid consumed during an exposure process or discharged from the photoresist.

### BRIEF DESCRIPTION OF THE DRAWINGS

FIGS. 1-3 are schematic cross-sectional views illustrating a process sequence in order to explain a method of forming patterns, according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

The illustrated embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

Unless otherwise noted, like reference numerals denote like elements throughout the attached drawings and the written description, and thus, duplicative descriptions thereof may not be provided.

In the drawings, the relative sizes of elements, layers, films, panels, and regions may be exaggerated for clarity, and thus the present disclosure is not limited thereto. In the drawings, the thickness of layers, films, panels, regions, etc., may be exaggerated for clarity. In the drawings, the thickness of a part of layers or regions, etc., may be exaggerated for clarity.

It will be understood that when an element such as a layer, film, region, or substrate is referred to as being “on” or “coupled to” another element, it can be directly on or coupled to the other element or one or more intervening elements may also be present. In addition, it will also be understood that when an element or layer is referred to as being “between” two elements or layers, it can be the only element or layer between the two elements or layers, or one or more intervening elements or layers may also be present.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “lower,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

As used herein, the singular forms “a,” “an” and “the” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items.

Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from a, b, and c,” “at least one from among a, b, and c,” “one from among a, b, and c”, “at least one of a to c” indicates only a, only b, only c, both a and b, both a and c, both b and c, all of a, b, and c, or variations thereof.

In the present disclosure, “substituted” refers to replacement of a hydrogen atom by deuterium, a halogen group, a hydroxyl group, an amino group, a substituted or unsubstituted C1 to C30 amine group, a nitro group, a substituted or unsubstituted C1 to C40 silyl group, a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a cyano group. “Unsubstituted” means that a hydrogen atom remains as a hydrogen atom without being replaced by another substituent.

In the present disclosure, the term “alkyl group” means a linear or branched aliphatic hydrocarbon group, unless otherwise defined. The alkyl group may be a “saturated alkyl group” that does not contain any double or triple bonds.

The alkyl group may be a C1 to C20 alkyl group. For example, the alkyl group may be a C1 to C10 alkyl group or a C1 to C6 alkyl group. For example, a C1 to C4 alkyl group means that the alkyl chain contains 1 to 4 carbon atoms, and may be (e.g., may be selected from) methyl, ethyl, propyl, iso-propyl, n-butyl, iso-butyl, sec-butyl, and/or t-butyl.

Specific examples of the alkyl group include a methyl group, an ethyl group, a propyl group, an isopropyl group, a butyl group, an isobutyl group, a t-butyl group, a pentyl group, a hexyl group, a cyclopropyl group, a cyclobutyl group, a cyclopentyl group, a cyclohexyl group, etc.

In the present disclosure, the term “cycloalkyl group” refers to a monovalent cyclic aliphatic hydrocarbon group, unless otherwise defined.

In the present disclosure, the term “alkenyl group”, unless otherwise defined, is a linear or branched aliphatic hydrocarbon group, and refers to an aliphatic unsaturated alkenyl group containing one or more double bonds.

In the present disclosure, the term “alkynyl group”, unless otherwise defined, is a linear or branched aliphatic hydrocarbon group, and refers to an unsaturated alkynyl group containing one or more triple bonds.

In the present disclosure, “aryl group” means a substituent in which all elements of a cyclic substituent have p-orbitals, and these p-orbitals form a conjugate. It may include monocyclic or polycyclic of fused ring (i.e., rings that share adjacent pairs of carbon atoms) functional groups.

Hereinafter, a metal-containing photoresist developer composition according to one or more embodiments is described.

A metal-containing photoresist developer composition according to one or more embodiments includes an organic solvent, an acid compound, and a conjugate base compound of the acid compound.

The acid compound may be included in an amount of about 0.01 to about 10 wt % based on a total wt % of the metal-containing photoresist developer composition.

It may be included in about 0.01 wt % to about 5 wt % within the above range, for example about 0.05 wt % to about 5 wt %, for example about 0.1 wt % to about 5 wt %.

The conjugate base compound may be included in an amount of about 0.001 wt % to about 1 wt % based on a total wt % of the metal-containing photoresist developer composition.

It may be included in about 0.001 wt % to about 0.5 wt % within the above range, for example about 0.01 wt % to about 0.5 wt %, for example about 0.05 wt % to about 0.5 wt %.

In the composition, an instantaneous pH imbalance may occur during development due to acid consumed during development or discharged from the photoresist. Instability caused by pH imbalance can be reduced by adding a conjugate base to form a similar buffer system. Accordingly, as the instability caused by pH imbalance is reduced, the problem that CD deviation may occur is resolved or reduced, and CD distribution and line edge roughness (LER) can be reduced.

The acid compound and the conjugate base compound may be included in a weight ratio of about 1:0.01 to about 1:1.

Within the above ranges, they may be included in a weight ratio of about 1:0.03 to about 1:1, for example, about 1:0.05 to about 1:1.

If (e.g., when) the mixing ratio of the acid compound and the conjugate base compound is within the above ranges, even if (e.g., when) a buffer system is formed and pH imbalance occurs, rapid pH change may not occur because the acid-base is in balance, and as the composition is stabilized, problems that may cause existing CD deviations are reduced, and stable results can be secured in CD distribution and LER.

The conjugate base compound according to one or more embodiments may be derived from an ammonium salt, an alkali metal salt, an alkaline earth metal salt, or a combination thereof.

Examples of the organic solvent included in the metal-containing photoresist developer composition according to one or more embodiments may include at least one of ether, alcohol, glycol ether, aromatic hydrocarbon compounds, ketone, and/or ester, but the present disclosure is not limited thereto. For example, the organic solvent may include ethylene glycol monomethyl ether, ethylene glycol monoethyl ether, methyl cellosolve acetate, ethyl cellosolve acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 4-methyl-2-pentanol (or referred to as methyl isobutyl carbinol (MIBC)), hexanol, 1-methoxy-2-propanol, 1-ethoxy-2-propanol, ethylene glycol, propylene glycol, heptanone, propylene carbonate, butylene carbonate, toluene, xylene, methylethylketone, cyclopentanone, cyclohexanone, 2-hydroxy ethyl propionate, 2-hydroxy-2-methyl ethyl propionate, ethoxy ethyl acetate, hydroxy ethyl acetate, 2-hydroxy-3-methyl methyl butanoate, 3-methoxy methyl propionate, 3-methoxy ethyl propionate, 3-ethoxy ethyl propionate, 3-ethoxy methyl propionate, methyl pyruvate, ethyl pyruvate, ethyl acetate, butyl acetate, ethyl lactate, butyl lactate, gamma-butyrolactone, methyl-2-hydroxyisobutyrate, methoxybenzene, n-butyl acetate, 1-methoxy-2-propyl acetate, methoxy ethoxy propionate, ethoxy ethoxy propionate, or a combination thereof, but the present disclosure is not limited thereto.

If (e.g., when) the other additives to be described in more detail later are included, the organic solvent may be included in a balance amount except for the components.

The metal-containing photoresist developer composition according to one or more embodiments may further include at least one other additive of (e.g., at least one other additive selected from) a surfactant, a dispersant, a moisture absorbent, and/or a coupling agent.

A metal-containing photoresist composition (which may be used with the metal-containing photoresist developer composition described above) may include a metal compound including at least one of an organic tin oxo group and/or an organic tin carboxyl group.

For example, the metal-containing photoresist composition may include a metal compound represented by Chemical Formula 1.

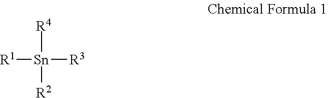

In Chemical Formula 1, R¹ may be (e.g., is selected from) a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, and/or —R^{a}—O—R^{b} (wherein R^{a} is a substituted or unsubstituted C1 to C20 alkylene group and R^{b} is a substituted or unsubstituted C1 to C20 alkyl group), R² to R⁴ are each independently selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, —OR^{c} or —OC(═O)R^{d}, at least one of R² to R⁴ are each independently (e.g., are each independently selected from) —OR^{c} or —OC(═O)R^{d}, R^{c} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and R^{d} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof. R^{c} and R^{d} may each independently be a substituted or unsubstituted C1 to C20 alkyl group.

Meanwhile, according to one or more embodiments, a method of forming patterns includes the step (e.g., act or task) of development using the aforementioned metal-containing photoresist developer composition. For example, the manufactured pattern may be a negative-type or kind photoresist pattern.

A method of forming patterns according to one or more embodiments includes coating a metal-containing photoresist composition on a substrate, drying and heating the resultant (e.g., the metal-containing photoresist composition) to form a metal-containing photoresist film on the substrate, exposing the metal-containing photoresist film, and developing the same using the aforementioned metal-containing photoresist developer composition.

For example, the forming of patterns using the metal-containing photoresist composition may include coating a metal-containing photoresist composition on a substrate on which a thin film is formed by spin coating, slit coating, inkjet printing, etc., and drying the coated metal-containing photoresist composition to form a photoresist film. The metal-containing photoresist composition may include a tin-based compound, and for example, the tin-based compound may include at least one of an alkyl tin oxo group, an alkyl tin carboxyl group, and/or an alkyl tin hydroxy group.

Subsequently, a composition for removing edge beads from the metal-containing photoresist composition may be coated along the edge of the substrate.

Next, a first heat treatment process of heating the substrate on which the metal-containing photoresist film is formed is performed. The first heat treatment process may be performed at a temperature of about 80° C. to about 120° C. In this process, the solvent is evaporated and the metal-containing photoresist film may be more firmly adhered to the substrate.

In one or more embodiments, the photoresist film is selectively exposed.

For example, examples of light that may be utilized in the exposure process may include not only light having a short wavelength such as i-line (wavelength 365 nm), KrF excimer laser (wavelength of 248 nm), ArF excimer laser (wavelength of 193 nm), but also EUV (light having a high energy wavelength such as EUV (Extreme UltraViolet, wavelength of 13.5 nm), E-Beam (electron beam), etc.

For example, the light for exposure according to one or more embodiments may be short-wavelength light having a wavelength range of about 5 nm to about 150 nm, and/or light having a high energy wavelength such as EUV (Extreme UltraViolet, wavelength 13.5 nm), E-beam (electron beam), etc.

In the step (e.g., act or task) of forming the photoresist pattern, a negative-type or kind pattern may be formed.

The exposed region of the photoresist film has a solubility different from that of the unexposed region of the photoresist film as a polymer is formed by a crosslinking reaction such as condensation between organometallic compounds.

Then, a second heat treatment process is performed on the substrate. The second heat treatment process may be performed at a temperature of about 90° C. to about 200° C. By performing the second heat treatment process, the exposed region of the photoresist film becomes difficult to be dissolved in a developer solution.

For example, the photoresist pattern corresponding to the negative-type or kind tone image may be completed by dissolving and then removing the photoresist film corresponding to the unexposed region using the aforementioned photoresist developer solution.

As described above, the photoresist pattern formed by exposure to not only light having a short wavelength such as i-line (wavelength of 365 nm), KrF excimer laser (wavelength of 248 nm), ArF excimer laser (wavelength of 193 nm), but also light having a high energy such as EUV (Extreme UltraViolet; wavelength of 13.5 nm) and an E-beam (electron beam), may have a thickness of about 5 nm to about 100 nm. For example, the photoresist pattern may be formed to have a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In contrast, the photoresist pattern may have a pitch having a half-pitch of less than or equal to about 50 nm, for example less than or equal to about 40 nm, for example less than or equal to about 30 nm, for example less than or equal to about 20 nm, for example less than or equal to about 15 nm, and a line width roughness of less than or equal to about 10 nm, less than or equal to about 5 nm, less than or equal to about 3 nm, or less than or equal to about 2 nm.

Hereinafter, a method of forming patterns is described in detail with reference to the drawings.

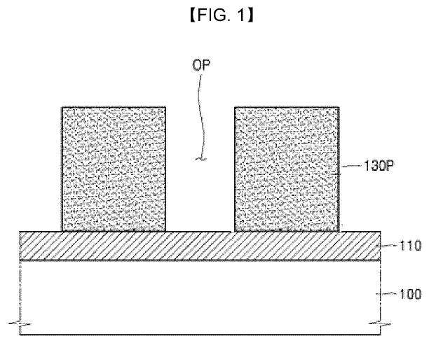

FIGS. 1 to 3 are schematic cross-sectional views illustrating a process sequence in order to explain a method of forming patterns, according to one or more embodiments of the present disclosure.

Referring to FIG. 1, the exposed photoresist film on the substrate 100 is developed to form a photoresist pattern 130P.

In one or more embodiments, the exposed photoresist film may be developed to remove an unexposed region of the photoresist film, and the photoresist pattern 130P including the exposed region of the photoresist film may be formed. The photoresist pattern 130P may include a plurality of openings OP.

In one or more embodiments, the development of the photoresist film may be performed through a negative-tone development (NTD) process. Herein, the metal-containing photoresist developer composition according to one or more embodiments may be utilized as a developer composition.

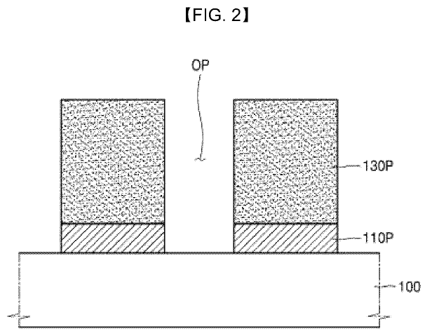

Referring to FIG. 2, the photoresist pattern 130P is utilized to process a feature layer 110 in the result of FIG. 1.

For example, the feature layer 110 is processed through various suitable processes of etching a feature layer 110 exposed through the openings OP of the photoresist pattern 130P, injecting impurity ions into the feature layer 110, forming an additional film on the feature layer 110 through the openings OP, deforming a portion of the feature layer 110 through the openings OP, and/or the like. FIG. 2 illustrates an example process of processing a feature pattern 110P by etching the feature layer 110 exposed through the openings OP.

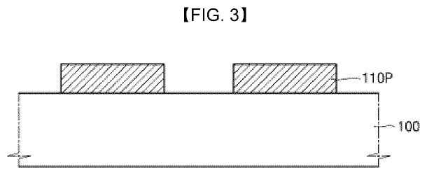

Referring to FIG. 3, the photoresist pattern 130P remaining on the feature pattern 110P is removed from the result of FIG. 2. In order to remove the photoresist pattern 130P, an ashing and stripping process may be utilized.

Hereinafter, the present disclosure will be described in more detail through examples relating to the preparation of the aforementioned metal-containing photoresist developer composition. However, the technical features of the present disclosure are not limited by the following examples.

### Preparation of Metal-Containing Photoresist Developer Composition

An organic solvent (PGMEA) and additives were mixed in a polypropylene (PP) bottle for each composition shown in Table 1, and then shaken until completely dissolved at room temperature (25° C.). Subsequently, the obtained solutions were filtered through a polytetrafluoroethylene PTFE filter with a pore size of 1 μm, obtaining developing solution compositions.

TABLE 1

| | | Additives | | | | |
|---|---|---|---|---|---|---|
| | Organic | | Compositions | | | |
| | solvent | Content | | Conjugate base | Mixed weight ratio | |
| | (wt %) | (wt %) | acid compound | compound | (acid:conjugate base) | std |
| Ex. 1 | 96.7 | 3.3 | acetic acid | ammonium | 1:0.1 | 5 |
| | | | | salt | | |
| Ex. 2 | 97.8 | 2.2 | glycolic acid | ammonium | 1:0.1 | 6 |
| | | | | salt | | |
| Ex. 3 | 99.8 | 0.2 | sulfuric acid | ammonium | 1:0.1 | 3 |
| | | | | salt | | |
| Ex. 4 | 99.8 | 0.2 | phosphonic acid | ammonium | 1:0.1 | 5 |
| | | | | salt | | |
| Ex. 5 | 99.8 | 0.2 | methyl | ammonium | 1:0.1 | 4 |
| | | | Phosphonic acid | salt | | |
| Ex. 6 | 99.7 | 0.3 | vinyl | ammonium | 1:0.5 | 3 |
| | | | Phosphonic acid | salt | | |
| Ex. 7 | 98.9 | 1.1 | formic acid | sodium salt | 1:0.1 | 2 |
| Ex. 8 | 96.8 | 3.2 | propionic acid | sodium salt | 1:0.07 | 5 |
| Ex. 9 | 97.9 | 2.1 | succinic acid | sodium salt | 1:0.05 | 3 |
| Ex. 10 | 96.7 | 3.3 | acetic acid | potassium salt | 1:0.1 | 3 |
| Ex. 11 | 96.8 | 3.2 | propionic acid | potassium salt | 1:0.07 | 4 |
| Ex. 12 | 96 | 4 | succinic acid | potassium salt | 1:1 | 5 |
| Ex. 13 | 99.7 | 0.3 | vinyl | sodium salt | 1:0.3 | 2 |
| | | | Phosphonic acid | | | |
| Ex. 14 | 99.8 | 0.2 | vinyl | sodium salt | 1:0.2 | 3 |
| | | | Phosphonic acid | | | |
| Ex. 15 | 99.7 | 0.3 | vinyl | sodium salt | 1:0.5 | 1 |
| | | | Phosphonic acid | | | |
| Comp. | 97 | 3 | acetic acid | — | — | 12 |
| Ex. 1 | | | | | | |
| Comp. | 98 | 2 | glycolic acid | | | 10 |
| Ex. 2 | | | | | | |
| Comp. | 99.9 | 0.1 | sulfuric acid | | | 14 |
| Ex. 3 | | | | | | |
| Comp. | 99.8 | 0.2 | phosphonic acid | | | 12 |
| Ex. 4 | | | | | | |
| Comp. | 99.8 | 0.2 | methyl | | | 10 |
| Ex. 5 | | | Phosphonic acid | | | |
| Comp. | 99.8 | 0.2 | vinyl | | | 11 |
| Ex. 6 | | | Phosphonic acid | | | |

### Preparation of Metal-Containing Photoresist Composition

An organometallic compound with a structural unit represented by Chemical Formula C was dissolved in 4-methyl-2-pentanol at a concentration of 1 wt % and then filtered with a 0.1 μm PTFE syringe filter, preparing a metal-containing photoresist composition.

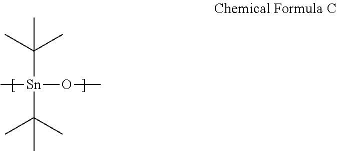

### Evaluation 1: CD Measurement

The developing solutions were evaluated by injecting each of them during the coating-exposure-development process for manufacturing a pattern wafer. When the process was completed, the pattern wafer, on which a line/space CD pattern was formed, was transferred to a CD-SEM measuring device to measure a CD (critical dimension) size. The CD size was measured at 10 points in the CD-SEM image, from which an average and a standard deviation (std) were calculated, and the standard deviations (std) are shown in Table 1.

Referring to Table 1, when the metal-containing photoresist developer compositions according to Examples 1 to 15 are applied, compared with when the metal-containing photoresist developer compositions according to Comparative Examples 1 to 6 are applied, excellent or suitable distribution characteristics are achieved.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within +30%, 20%, 10%, 5% of the stated value.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

The light emitting device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

Reference Numerals

| | |
|---|---|
| 100: substrate | OP: opening |
| 110: feature layer | 110P: feature pattern |
| 130P: photoresist pattern | |

What is claimed is:

1. A metal-containing photoresist developer composition comprising:
an organic solvent,
an acid compound, and
a conjugate base compound of the acid compound.

2. The metal-containing photoresist developer composition as claimed in claim 1, wherein the acid compound is about 0.01 wt % to about 10 wt % based on a total wt % of the metal-containing photoresist developer composition.

3. The metal-containing photoresist developer composition as claimed in claim 1, wherein the conjugate base compound is about 0.001 wt % to about 1 wt % based on a total wt % of the metal-containing photoresist developer composition.

4. The metal-containing photoresist developer composition as claimed in claim 1, wherein the acid compound and the conjugate base compound have a weight ratio of about 1:0.01 to about 1:1.

5. The metal-containing photoresist developer composition as claimed in claim 1, wherein the conjugate base compound is derived from an ammonium salt, an alkali metal salt, an alkaline earth metal salt, or a combination thereof.

6. A system for forming a photoresist pattern, the system comprising:
the metal-containing photoresist developer composition as claimed in claim 1, and a metal-containing photoresist comprising a metal compound comprising at least one of an organic tin oxo group or an organic tin carboxyl group.

7. The system for forming a photoresist pattern as claimed in claim 6, wherein the metal compound is represented by Chemical Formula 1: 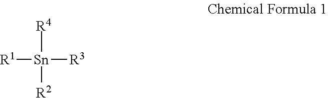
wherein, in Chemical Formula 1,
R¹ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or —R^{a}—O—R^{b} (wherein R^{a} is a substituted or unsubstituted C1 to C20 alkylene group and R^{b} is a substituted or unsubstituted C1 to C20 alkyl group),
R² to R⁴ are each independently selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, —OR^{c} or —OC(═O)R^{d}, at least one of R² to R⁴ are each independently selected from —OR^{c} or —OC(═O)R^{d},
R^{c} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{d} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

8. The metal-containing photoresist developer composition as claimed in claim 7, wherein R^{c} and R^{d} are each independently a substituted or unsubstituted C1 to C20 alkyl group.

9. A method of forming patterns, comprising:
coating a metal-containing photoresist composition on a substrate;
drying and heating the metal-containing photoresist composition to form a metal-containing photoresist film on the substrate;
exposing the metal-containing photoresist film to light; and
developing the metal-containing photoresist film using the metal-containing photoresist developer composition according to claim 1.
